(19) United States
(12) Patent Application Publication
(10) Pub. No.: US 2016/0376702 A1
(43) Pub. Date: Dec. 29, 2016

(54) DUAL MODE CHAMBER FOR PROCESSING WAFER-SHAPED ARTICLES

(71) Applicant: LAM RESEARCH AG, Villach (AT)

(72) Inventors: Karl-Heinz HOHENWARTER, DELLACH/GAIL (AT); Michael PUGGL, VILLACH (AT); Reinhold SCHWARZENBACHER, REISSECK (AT); Milan PLISKA, VILLACH (AT)

(73) Assignee: LAM RESEARCH AG

(21) Appl. No.: 14/752,710

(22) Filed: Jun. 26, 2015

(51) Int. Cl. C23C 16/458

(52) U.S. Cl. CPC C23C 16/458

(57) ABSTRACT

An apparatus for processing a wafer shaped article comprises a rotary chuck for holding a wafer shaped article and rotating the wafer shaped article about an axis of rotation. A chamber surrounds and encloses the rotary chuck, the chamber comprising an upper opening. A lid is mounted externally of the chamber so as to be movable between a closed position in which the lid seals the upper opening, and an open position in which the lid uncovers the upper opening and is displaced laterally therefrom. The chamber is openable separately from the lid so as to permit a wafer shaped article to be introduced into the chamber in a direction perpendicular to the axis of rotation.

### BACKGROUND OF THE INVENTION

1. Field of the Invention The invention relates generally to apparatus for processing wafer-shaped articles, such as semiconductor wafers, wherein a wafer-shaped article is introduced into and removed from a process chamber.

2. Description of Related Art

Semiconductor wafers are subjected to various surface treatment processes such as etching, cleaning, polishing and material deposition. To accommodate such processes, a single wafer may be supported in relation to one or more treatment fluid nozzles by a chuck associated with a rotatable carrier, as is described for example in U.S. Pat. Nos. 4,903,717 and 5,513,668.

Alternatively, a chuck in the form of a ring rotor adapted to support a wafer may be located within a closed process chamber and driven without physical contact through an active magnetic bearing, as is described for example in International Publication No. WO 2007/101764 and U.S. Pat. No. 6,485,531. Treatment fluids which are driven outwardly from the edge of a rotating wafer due to centrifugal action are delivered to a common drain for disposal.

Conventional process chambers operate in one mode only, i.e., they are either always closed or always open during use. Closed process chambers are used to contain the hazardous substances used for wafer processing, as well as to maintain a superatmospheric pressure for those processes requiring such a condition, as disclosed for example in commonly-owned copending application US 2013/0062839.

Closed chambers are opened only for loading or unloading a wafer. For this purpose such chambers are either top-loaders or side-loaders, as in commonly-owned copending application US 2013/0101372.

However, it would be desirable to provide a dual mode process chamber that would provide a closed environment for some process sequences and an open environment in other process sequences. This would be especially useful, for example, for successively subjecting a wafer to ozone treatment in a closed chamber followed by a cleaning sequence in an open chamber, without the need to remove the wafer between the ozone and cleaning treatments.

### SUMMARY OF THE INVENTION

Thus, in one aspect, the present invention relates to an apparatus for processing a wafer shaped article, comprising a rotary chuck for holding a wafer shaped article and rotating the wafer shaped article about an axis of rotation. A chamber surrounds and encloses the rotary chuck, the chamber comprising an upper opening. A lid is mounted externally of the chamber so as to be movable between a closed position in which the lid seals the upper opening, and an open position in which the lid uncovers the upper opening and is displaced laterally therefrom. The chamber is openable separately from the lid so as to permit a wafer shaped article to be introduced into the chamber in a direction perpendicular to the axis of rotation.

In preferred embodiments of the apparatus according to this aspect of the present invention, the rotary chuck comprises a rotor having a circular series of gripping pins positioned so as to releasably secure a wafer shaped article to the rotor.

In preferred embodiments of the apparatus according to this aspect of the present invention, the gripping pins depend downwardly from the rotary chuck.

In preferred embodiments of the apparatus according to this aspect of the present invention, the rotary chuck is an annular rotor.

In preferred embodiments of the apparatus according to this aspect of the present invention, the annular rotor is a magnetic rotor.

In preferred embodiments of the apparatus according to this aspect of the present invention, the chamber further comprises a side opening and a door that is mounted so as to be movable between a process position in which the door seals the side opening, and a loading and unloading position in which the door uncovers the side opening and is laterally displaced therefrom, so as to allow loading and unloading of a wafer shaped article into and from the chamber.

In preferred embodiments of the apparatus according to this aspect of the present invention, a liquid dispenser is mounted externally of the chamber so as to be movable between a standby position in which a dispensing nozzle of the liquid dispenser is displaced laterally from the upper opening of the chamber, and a service position in which the dispensing nozzle is positioned overlying the upper opening.

In preferred embodiments of the apparatus according to this aspect of the present invention, the liquid dispenser is movable to the service position only when the lid is in the open position.

In preferred embodiments of the apparatus according to this aspect of the present invention, a motorized mechanism is provided for moving the lid between the open and closed positions.

In preferred embodiments of the apparatus according to this aspect of the present invention, the side door comprises a motorized mechanism for moving the side door between the closed and loading and unloading positions.

In preferred embodiments of the apparatus according to this aspect of the present invention, the lid has a lower portion configured as a gas showerhead so as to supply a gas into the chamber when the lid is in the sealed position.

In preferred embodiments of the apparatus according to this aspect of the present invention, the lid has at least one liquid nozzle so as to dispense liquid onto an upwardly facing surface of a wafer shaped article when positioned on the rotary chuck.

In preferred embodiments of the apparatus according to this aspect of the present invention, at least one liquid dispenser is mounted internally of the chamber, and is positioned so as to dispense liquid onto a downwardly facing surface of a wafer shaped article when positioned on the rotary chuck.

In preferred embodiments of the apparatus according to this aspect of the present invention, the annular rotor has an inner diameter that is less than a diameter of a wafer shaped article that the rotary chuck is configured to hold.

In preferred embodiments of the apparatus according to this aspect of the present invention, the chamber comprises a vertically-movable lower cover that is movable between a closed position in which the cover and an upper portion of the chamber define a sealed chamber enclosing the rotary chuck, and an open position that permits loading and unloading of a wafer-shaped article.

In preferred embodiments of the apparatus according to this aspect of the present invention, the vertically-movable lower cover comprises a splash-guard surrounding the wafer shaped article when positioned on the spin chuck.

In preferred embodiments of the apparatus according to this aspect of the present invention, the lid has a downwardly projecting element that projects into the central opening of the annular rotor.

In preferred embodiments of the apparatus according to this aspect of the present invention, the downwardly projecting element has an outer diameter that is smaller than the inner diameter of the annular rotor by at least 0.1 mm and not more than 50 mm.

In a preferred embodiment of the apparatus according to this aspect of the present invention, the apparatus further comprises a cleaning station for cleaning the lid while it is in an open position in which the lid uncovers the upper opening and is displaced laterally from the upper opening.

Such cleaning station may comprise at least one liquid dispensing nozzle for dispensing at least on kind of liquid to the downwardly facing surface of the lid, as well as a liquid collector.

In another aspect, the present invention relates to an apparatus for processing a wafer shaped article, comprising a rotary chuck for holding a wafer shaped article and rotating the wafer shaped article about an axis of rotation. A chamber surrounds and encloses the rotary chuck, the chamber comprising an upper opening. A lid is mounted externally of the chamber so as to be movable between a closed position in which the lid seals the upper opening, and an open position in which the lid uncovers the upper opening and is displaced laterally therefrom. A liquid dispenser is mounted externally of the chamber so as to be movable between a standby position in which a dispensing nozzle of the liquid dispenser is displaced laterally from the upper opening of the chamber, and a service position in which the dispensing nozzle is positioned overlying the upper opening.

In preferred embodiments of the apparatus according to this aspect of the present invention, the liquid dispenser is movable to the service position only when the lid is in the open position.

In preferred embodiments of the apparatus according to this aspect of the present invention, the chamber is openable separately from the lid so as to permit a wafer shaped article to be introduced into the chamber in a direction perpendicular to the axis of rotation.

In preferred embodiments of the apparatus according to this aspect of the present invention, the rotary chuck is an annular rotor.

In preferred embodiments of the apparatus according to this aspect of the present invention, the annular rotor has an inner diameter that is less than a diameter of a wafer shaped article that the rotary chuck is configured to hold.

In preferred embodiments of the apparatus according to this aspect of the present invention, the chamber comprises a vertically-movable lower cover that is movable between a closed position in which the cover and an upper portion of the chamber define a sealed chamber enclosing the rotary chuck, and an open position that permits loading and unloading of a wafer-shaped article.

In yet another aspect, the present invention relates to a process for treating a wafer shaped article, comprising loading a wafer shaped article onto a rotary chuck positioned within a chamber, and closing the chamber. The rotary chuck is rotates ?? so as to rotate the wafer shaped article, while introducing a process fluid such as ozone gas or a concentrated acid into the closed chamber. The chamber is then opened by lifting an upper lid of the chamber and moving the lid laterally so as to uncover an upper opening of the chamber. A rinse liquid is then dispensed onto the wafer shaped article through the upper opening.

In preferred embodiments of the process according to this aspect of the present invention, the loading comprises opening a side door of the chamber, introducing the wafer shaped article into the chamber through the side door, and closing the side door so as to seal the chamber.

In preferred embodiments of the process according to this aspect of the present invention, the dispensing comprises moving a liquid dispenser from a standby position in which a dispensing nozzle of the liquid dispenser is offset laterally from the upper opening of the chamber, to a service position in which the dispensing nozzle overlies the upper opening.

In preferred embodiments of the process according to this aspect of the present invention, the liquid dispenser is movable to its service position only after the lid has been moved laterally away from the upper opening.

In preferred embodiments of the process according to this aspect of the present invention, a process liquid is dispensed onto the wafer shaped article via at least one internal liquid dispenser while ozone gas is introduced into the chamber.

### BRIEF DESCRIPTION OF THE DRAWINGS

Other objects, features and advantages of the invention will become more apparent after reading the following detailed description of preferred embodiments of the invention, given with reference to the accompanying drawings, in which:

FIG. 1 is an explanatory cross-sectional side view of a process chamber according to a first embodiment of the invention, with a side door shown in its second position and an interior cover shown in its first position;

FIG. 2 is an explanatory cross-sectional side view of a process chamber according to the first embodiment of the invention, with the side door shown in its first position and the interior cover shown in its second position;

FIG. 3 is a view corresponding to that of FIG. 2, in which the upper lid has been raised by its associated motorized mechanism so as to open the process chamber from above;

FIG. 4 is a view following that of FIG. 3, in which the upper lid has also been moved laterally by its associated motorized mechanism so as to uncover the upper opening of the process chamber;

FIG. 5 is a perspective view of the upper lid of the embodiment of FIGS. 1-4 and its associated motorized mechanism;

FIG. 6 is a perspective view like that of FIG. 5 showing the lid moved away from the chamber, and showing an optional cleaning station for the lid;

FIG. 7 is a sectional view of the upper lid of the embodiment of FIGS. 1-4;

FIG. 8 is an explanatory plan view showing the relative positions of the upper lid and the externally-mounted liquid dispenser during respectively different operating modes of the process chamber of the embodiment of FIGS. 1-4;

FIG. 9 is a view corresponding to that of FIG. 1, of an apparatus according to a second embodiment of the present invention;

FIG. 10 is a view corresponding to that of FIG. 2, of the apparatus of FIG. 9;

FIG. 11 is a view corresponding to that of FIG. 1, of an apparatus according to a third embodiment of the present invention; and

FIG. 12 is a view corresponding to that of FIG. 2, of the apparatus of FIG. 11.

### DETAILED DESCRIPTION OF PREFERRED EMBODIMENTS

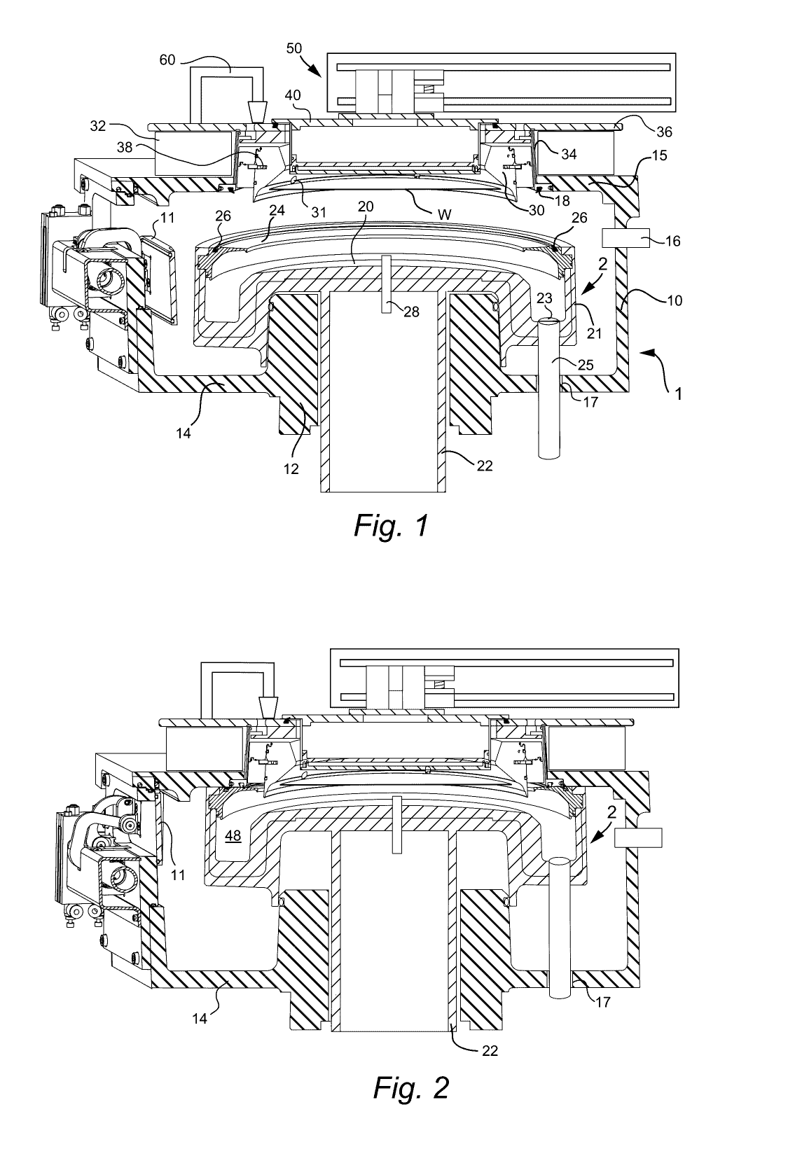

Referring now to FIG. 1, an apparatus for treating surfaces of wafer-shaped articles according to a first embodiment of the invention comprises an outer process chamber 1, which is preferably made of aluminum coated with PFA (perfluoroalkoxy) resin. The chamber in this embodiment has a main cylindrical wall 10, a lower part 12 and an upper part 15. From upper part 15 there extends a narrower cylindrical wall 34, which at its upper end joins the top structure 36 of chamber 1. The top structure 36 defines a central circular opening in this embodiment, which is shown in FIG. 1 as being closed by the upper lid 40.

Upper lid 40 is mounted externally of the chamber 1 via a motorized mechanism 50, which serves to displace the lid 40 relative to chamber 1 when moving the lid 40 between its open and closed positions, as will be described in detail herein. A liquid dispenser 60 is mounted externally of the chamber 1, and is shown in its stanby position in FIG. 1. Because the upper lid 40 is sealing the upper opening of the chamber 1, liquid dispenser 60 is unable to dispense liquid into the chamber 1 in this configuration.

A rotary chuck 30 is disposed in the upper part of chamber 1, and surrounded by the cylindrical wall 34. Rotary chuck 30 rotatably supports a wafer W during use of the apparatus. The rotary chuck 30 incorporates a rotary drive comprising ring gear 38, which engages and drives a plurality of eccentrically movable gripping members for selectively contacting and releasing the peripheral edge of a wafer W.

In this embodiment, the rotary chuck 30 is a ring rotor provided adjacent to the interior surface of the cylindrical wall 34. A stator 32 is provided opposite the ring rotor adjacent the outer surface of the cylindrical wall 34. The rotor 30 and stator 32 serve as a motor by which the ring rotor 30 (and thereby a supported wafer W) may be rotated through an active magnetic bearing. For example, the stator 32 can comprise a plurality of electromagnetic coils or windings that may be actively controlled to rotatably drive the rotary chuck 30 through corresponding permanent magnets provided on the rotor. Axial and radial bearing of the rotary chuck 30 may be accomplished also by active control of the stator or by permanent magnets. Thus, the rotary chuck 30 may be levitated and rotatably driven free from mechanical contact. Alternatively, the rotor may be held by a passive bearing where the magnets of the rotor are held by corresponding high-temperature-superconducting magnets (HTS-magnets) that are circumferentially arranged on an outer rotor outside the chamber. With this alternative embodiment each magnet of the ring rotor is pinned to its corresponding HTS-magnet of the outer rotor. Therefore the inner rotor makes the same movement as the outer rotor without being physically connected.

It will be noted that the upper lid 40 in this embodiment extends into the central open space defined by the annular rotor.

It will also be noted that the wafer W in this embodiment hangs downwardly from the rotary chuck 30, supported by the gripping members 31. Moreover, the wafer is positioned such that a horizontal plane bisecting the wafer intersects a downwardly facing inner surface of the annular rotor. If wafer W is a semiconductor wafer, for example of 300 mm or 450 mm diameter, the upwardly facing side of wafer W could be either the device side or the obverse side of the wafer W, which is determined by how the wafer is positioned on the rotary chuck 30, which in turn is dictated by the particular process being performed within the chamber 1.

The rotary chuck is designed to hold a wafer W of only a predetermined diameter, e.g., a 300 mm or 450 mm semiconductor wafer. Furthermore, the central opening of rotary chuck 30 has a diameter that is less than the diameter of the wafer W that the chuck 30 is designed to hold. Therefore, the wafer W could not be loaded onto the chuck 30 through the upper opening of the chamber without first removing the chuck 30 from the chamber, which would be highly impractical.

The apparatus of FIG. 1 further comprises an interior cover 2, which is movable relative to the process chamber 1. Interior cover 2 is shown in FIG. 1 in its first, or open, position, in which the rotary chuck 30 is in communication with the outer cylindrical wall 10 of chamber 1. Cover 2 in this embodiment is generally cup-shaped, comprising a base 20 surrounded by an upstanding cylindrical wall 21. Cover 2 furthermore comprises a hollow shaft 22 supporting the base 20, and traversing the lower wall 14 of the chamber 1.

Hollow shaft 22 is surrounded by a boss 12 formed in the main chamber 1, and these elements are connected via a dynamic seal that permits the hollow shaft 22 to be displaced relative to the boss 12 while maintaining a gas-tight seal with the chamber 1.

At the top of cylindrical wall 21 there is attached an annular deflector member 24, which carries on its upwardly-facing surface a gasket 26. Cover 2 preferably comprises a fluid medium inlet 28 traversing the base 20, so that process fluids and rinsing liquid may be introduced into the chamber onto the downwardly facing surface of wafer W.

Cover 2 furthermore includes a process liquid discharge opening 23, which opens into a discharge pipe 25. Whereas pipe 25 is rigidly mounted to base 20 of cover 2, it traverses the bottom wall 14 of chamber 1 via a dynamic seal 17 so that the pipe may slide axially relative to the bottom wall 14 while maintaining a gas-tight seal.

An exhaust opening 16 traverses the wall 10 of chamber 1 and is connected to suitable exhaust conduit (not shown). The position depicted in FIG. 1 corresponds to loading or unloading of a wafer W. In particular, a wafer W can be loaded onto the rotary chuck 30 through the side door 11, which is shown in its open, or second, position in FIG. 1, so as to permit loading or unloading of a wafer W.

In FIG. 2, the interior cover 2 has been moved to its second, or closed, position, which corresponds to processing of a wafer W. That is, after a wafer W is loaded onto rotary chuck 30, the door 11 is moved to its closed, or first, position as shown in FIG. 2, and the cover 2 is moved upwardly relative to chamber 1, by a suitable motor (not shown) acting upon the hollow shaft 22. The upward movement of the interior cover 2 continues until the deflector member 24 comes into contact with the interior surface of the upper part 15 of chamber 1. In particular, the gasket 26 carried by deflector 24 seals against the underside of upper part 15, whereas the gasket 18 carried by the upper part 15 seals against the upper surface of deflector 24.

When the interior cover 2 reaches its second position as depicted in FIG. 2, there is thus created a second chamber 48 within the closed process chamber 1. Inner chamber 48 is moreover sealed in a gas tight manner from the remainder of the chamber 1.

After a closed chamber process has been performed with the apparatus in the configuration shown in FIG. 2, it may be desirable to perform an open chamber process, such as rinsing, without the need to remove the wafer from the chamber and place it in a different apparatus.

For example, with the apparatus in the configuration shown in FIG. 2, a process may be performed in which ozone gas and/or a concentrated acid are introduced into the closed process chamber and into contact with the wafer W. However, for example for rinsing the wafer W, it may be preferable to conduct the rinsing in an open process chamber.

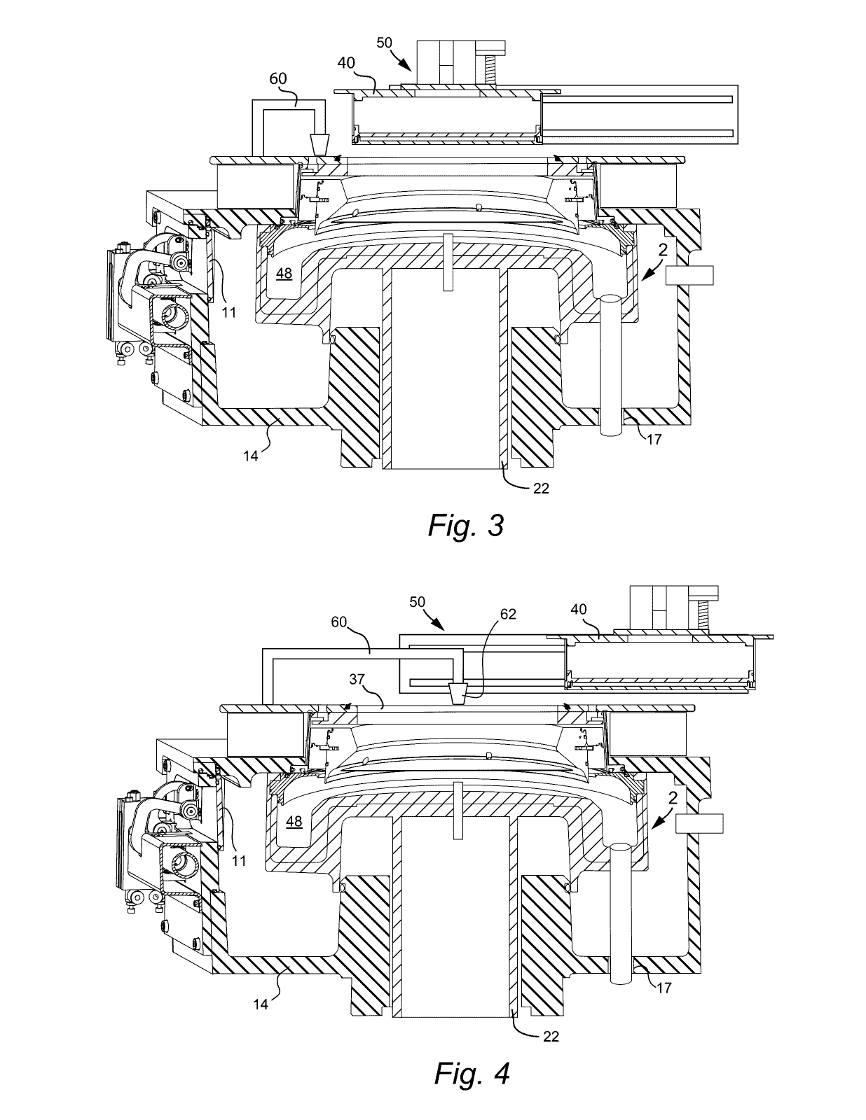

Thus, in FIG. 3, the process chamber 1 has been opened by raising the lid 40 with its associated motorized mechanism 50. Mechanism 50 then moves the lid 40 laterally relative to chamber 1 so as to uncover the upper opening 37 defined by the upper chamber structure 36, as shown in FIG. 4. With the lid in that position, as also shown in FIG. 4, the externally-mounted liquid dispenser 60 can now be swung into its use position, in which the discharge nozzle 62 overlies the wafer W through the opening 37.

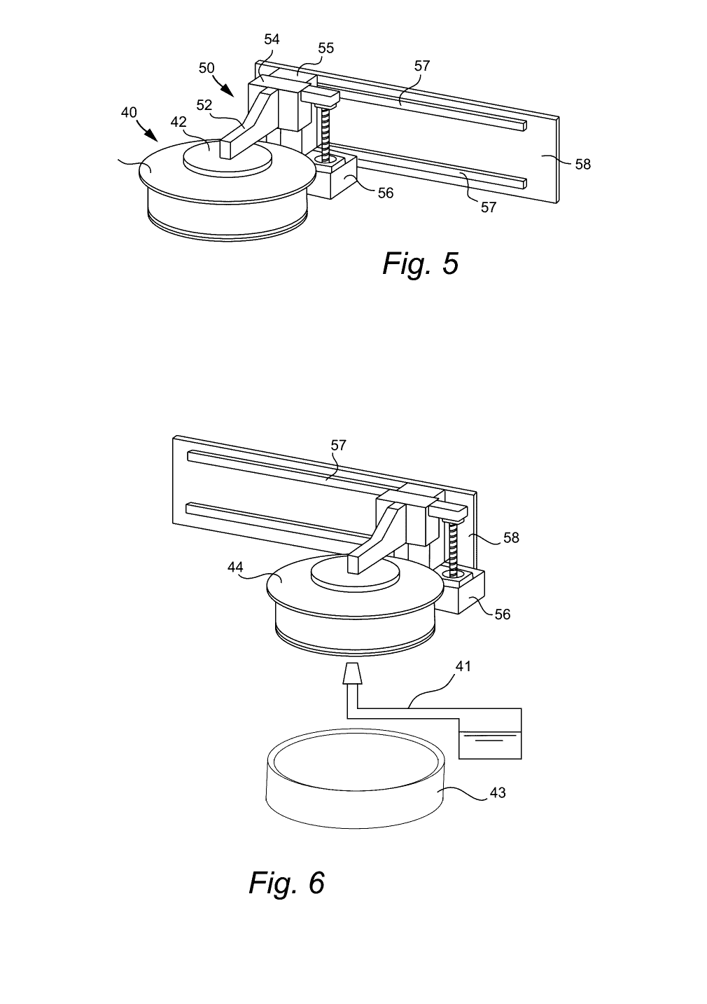

Referring now to FIGS. 5-7, the structure of the upper lid 40 and its associated motorized mechanism 50 will be described in greater detail. Upper lid 40 comprises a top plate 42 that is rigidly secured to an arm 52 of the motorized mechanism 50. The arm 52 is in turn rigidly secured to a mounting block 54 that can be moved vertically relative to slide block 55 by the operation of screw motor 56. Slide block 55 is displaceable via an internal motor horizontally along the pair of rails 57, which are carried on a plate 58 mounted to the frame of the apparatus.

Thus, operation of the screw motor 56 causes the lid 40 to be raised relative to the chamber 1, whereas operation of the motor of the slide block 55 causes the lid 40 to be moved laterally relative to the chamber 1. It will be appreciated that any other mechanism capable of achieving the desired displacement of the lid 40 may be utilized in place of that shown, and that the upward and lateral movement of the lid 40 relative to chamber 1 may if desired be effected simultaneously once the lid 40 has cleared the opening 37 in chamber 1.

The upward and lateral movement of the lid 40 need not have distinct components, e.g., the upward and lateral movement may be accomplished by mounting the lid 40 to an exterior surface of the chamber or to another supporting structure via a hinge provided at one lateral side of the lid. The upward movement of the lid as discussed herein thus does not require that the lid in its entirety be moved upwardly, as in the case of a hinged mounting a portion of the lid adjacent the hinge would not necessarily be moved upwardly.

As shown in FIG. 6, the apparatus may also be provided with a cleaning station to clean the underside of the lid 40 when it is removed from the chamber 1. For example, the cleaning station may comprise a liquid dispenser 41 comprising an upwardly directed nozzle communicating with a reservoir of cleaning fluid, and a collector 43 for receiving the used rinsing liquid after it is dispensed onto the underside of the lid 40.

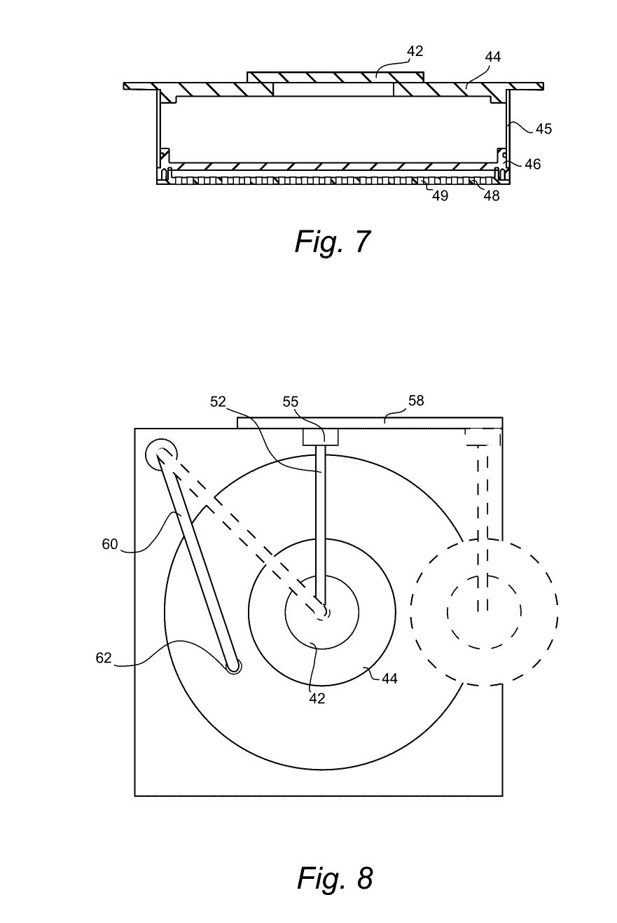

As shown in FIG. 7, the upper lid 40 preferably has a drum-like structure, comprising upper plate 44 to which top plate 42 is rigidly secured, and which is joined to a lower plate 46 by a cylindrical wall 45. A bottom plate 48 is secured to the lower plate 46 in this embodiment, the bottom plate having a multiplicity of orifices 49 formed in a two-dimensional array so as to constitute a gas showerhead for introducing a gas such as ozone into the closed chamber 1 via the upper lid 40, the space between plates 46 and 48 in this embodiment thus serving as a gas distribution manifold.

The lid 40 may also have at least one liquid dispensing nozzle for dispensing at least one liquid onto the upwardly facing surface of the wafer shaped article. Such nozzle can be arranged in the center of the downwardly facing surface of the lid or may be arranged eccentrically.

Turning now to FIG. 8, the coordinated movements of the externally mounted liquid dispenser 60 and the lid 40 are shown. In particular, the solid line positions correspond to FIGS. 1 and 2, whereas the broken line positions correspond to FIG. 4. It will be seen that the externally mounted liquid dispenser 60 in this embodiment is mounted for pivotal movement in the manner of a boom swing arm, although the dispenser could if desired be mounted for linear movement.

In practice the movements illustrated in FIG. 8 will be mechanized and controlled by the computer that governs the overall operation of the apparatus.

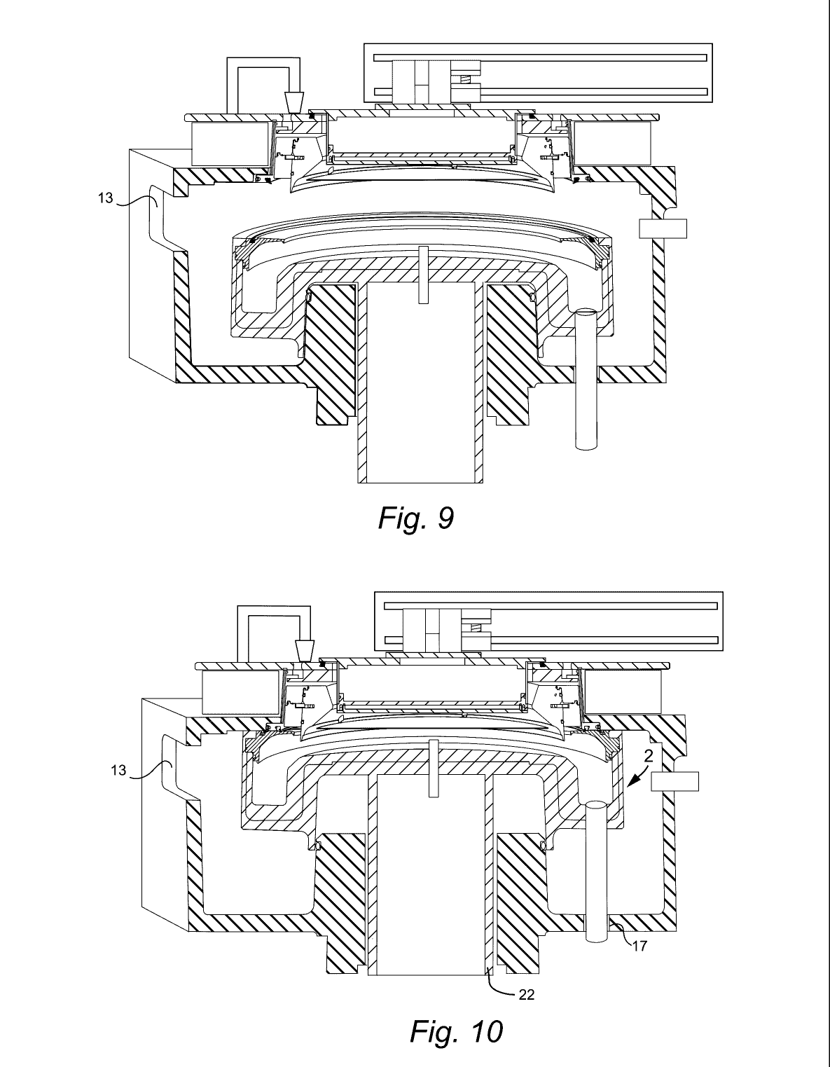

FIGS. 9 and 10 show a second embodiment, which differs from the first embodiment in that the side door and its associated opening and closing mechanism are omitted. Instead, an elongated opening 13 is provided, which is of the appropriate size to receive a wafer W carried by its known transfer mechanism.

It will be appreciated that in this embodiment the outer chamber is never entirely closed, and the only sealed chamber is therefore that formed when the inner cover is in the position shown in FIG. 10.

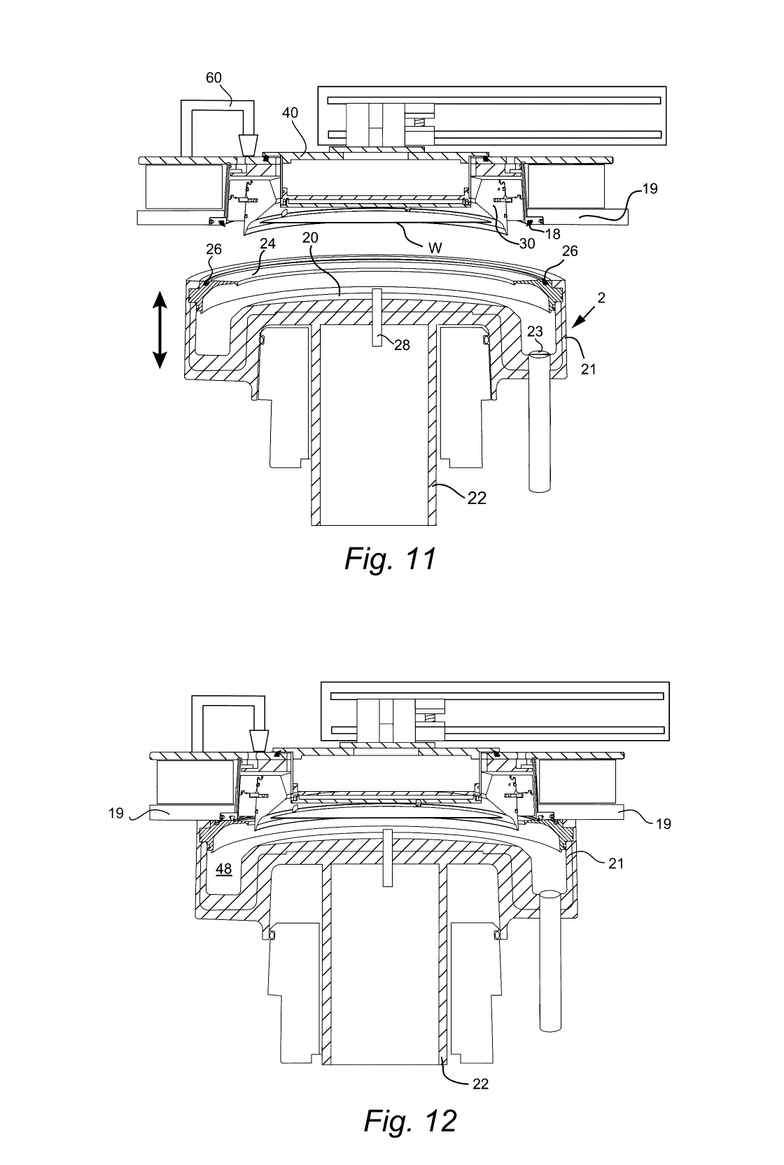

FIGS. 11 and 12 show a third embodiment, which differs from the second embodiment in that the lower outer chamber structure has been omitted entirely. Thus, in this embodiment, the only closed chamber is that formed by the cover 2 sealing against the plate 19 of the upper chamber structure, via sealing gaskets 18 and 26. In the position shown in FIG. 11, the gap between the lower cover 2 and the plate 19 provides clearance for loading and unloading a wafer W onto chuck 30. The structure and operation of this embodiment is otherwise as described above in connection with the preceding embodiments.

The foregoing description of preferred embodiments of the present invention is provided to aid those skilled in the art in appreciating the many other ways in which the present invention can be embodied and applied. It should not be viewed in a limiting sense, with the scope of the invention being instead as set forth in the appended claims.

What is claimed is:

1. An apparatus for processing a wafer shaped article, comprising a rotary chuck for holding a wafer shaped article and rotating the wafer shaped article about an axis of rotation; a chamber surrounding and enclosing the rotary chuck, said chamber comprising an upper opening; and a lid mounted externally of said chamber so as to be movable between a closed position in which said lid seals said upper opening, and an open position in which said lid uncovers said upper opening and is displaced laterally therefrom; said chamber being openable separately from said lid so as to permit a wafer shaped article to be introduced into said chamber in a direction perpendicular to said axis of rotation.

2. The apparatus according to claim 1, wherein said rotary chuck comprises a rotor having a circular series of gripping pins positioned so as to releasably secure a wafer shaped article to said rotor.

3. The apparatus according to claim 2, wherein said gripping pins depend downwardly from said rotary chuck.

4. The apparatus according to claim 1, wherein the rotary chuck is an annular rotor.

5. The apparatus according to claim 4, wherein the annular rotor is a magnetic rotor.

6. The apparatus according to claim 1, wherein said chamber further comprises a side opening and a door that is mounted so as to be movable between a process position in which said door seals said side opening, and a loading and unloading position in which said door uncovers said side opening and is laterally displaced therefrom, so as to allow loading and unloading of a wafer shaped article into and from said chamber.

7. The apparatus according to claim 1, further comprising a liquid dispenser mounted externally of said chamber so as to be movable between a standby position in which a dispensing nozzle of said liquid dispenser is displaced laterally from said upper opening of said chamber, and a service position in which said dispensing nozzle is positioned overlying said upper opening.

8. The apparatus according to claim 7, wherein said liquid dispenser is movable to said service position only when said lid is in said open position.

9. The apparatus according to claim 1, further comprising a motorized mechanism for moving said lid between said open and closed positions.

10. The apparatus according to claim 6, wherein said side door comprises a motorized mechanism for moving said side door between said closed and loading and unloading positions.

11. The apparatus according to claim 1, wherein said lid has a lower portion configured as a gas showerhead so as to supply a gas into said chamber when said lid is in said sealed position.

12. The apparatus according to claim 1, wherein said lid has at least one liquid nozzle so as to dispense liquid onto an upwardly facing surface of a wafer shaped article when positioned on said rotary chuck.

13. The apparatus according to claim 1, further comprising at least one liquid dispenser mounted internally of said chamber, and positioned so as to dispense liquid onto a downwardly facing surface of a wafer shaped article when positioned on said rotary chuck.

14. The apparatus according to claim 4, wherein said annular rotor has an inner diameter that is less than a diameter of a wafer shaped article that said rotary chuck is configured to hold.

15. The apparatus according to claim 1, wherein said chamber comprises a vertically-movable lower cover that is movable between a closed position in which said cover and an upper portion of said chamber define a sealed chamber enclosing said rotary chuck, and an open position that permits loading and unloading of a wafer-shaped article.

16. The apparatus according to claim 15, wherein said vertically-movable lower cover comprises a splash-guard surrounding the wafer shaped article when positioned on the spin chuck.

17. The apparatus according to claim 4, wherein the lid has a downwardly projecting element that projects into the central opening of the annular rotor.

18. The apparatus according to claim 17, wherein the downwardly projecting element has an outer diameter that is smaller than the inner diameter of the annular rotor by at least 0.1 mm and not more than 50 mm.

19. The apparatus according to claim 1, further comprising a cleaning station for cleaning the lid while it is in an open position in which the lid uncovers the upper opening and is displaced laterally from the upper opening.
